(19) United States
(12) Patent Application Publication
(10) Pub. No.: US 2002/0044072 A1
(43) Pub. Date: Apr. 18, 2002

(54) Key input device used for portable equipment

(76) Inventors: Koichi Suzumura, Oobu-city (JP); Katsuharu Hosoe, Okazaki-city (JP); Masayuki Yasuda, Kariya-city (JP)

Correspondence Address: LAW OFFICE OF DAVID G POSZ, 2000 L STREET, N.W., SUITE 200, WASHINGTON, DC, 20036, US

(21) Appl. No.: 09/977,391

(22) Filed: Oct. 16, 2001

(30) Foreign Application Priority Data
Oct. 18, 2000 (JP) 2000-318152
Apr. 13, 2001 (JP) 2001-115570

(51) Int. Cl. H03M 11/00; H03K 17/94

(52) U.S. Cl. 341/22

(57) ABSTRACT

A key input device according to the present invention includes a key holding unit having an outward shape which can be gripped by one hand and is structured as a separate part which is portable; at least five input keys which are provided on the key holding unit so as to allow separate operation of each of at least five input keys using each finger of one hand; and input units which are provided on the key holding unit in addition to at least five input keys, and which are operated in accordance with movement of the key holding unit; wherein input of characters are executed by combining at least five input keys with the input units. According to the present invention, it is possible to realize a key input device used for portable equipment in which a user can easily grip the key input device and easily execute an input operation of characters with a few operations of pushing buttons using one hand of the user.

### BACKGROUND OF THE INVENTION

1. Field of the Invention

The present invention relates to a key input device for executing an input operation, for characters, to a computer having various uses. According to the present invention, a user can easily grip the key input device and easily execute an input operation for characters using one hand, as explained in detail below.

2. Description of the Related Art

Conventionally, as a representative key input device for executing an input operation for characters, numerals and the like to a computer having various uses, there is a keyboard on which are arranged many input keys, exceeding one hundred, in accordance with a predetermined pattern. Usually, the keyboard is structured to allow a key operation using fingers of both hands of a user.

Further, in a key input device such as portable telephone which can be gripped by one hand, relatively few push buttons (i.e. input keys) are provided on a limited and narrow area, and the push buttons are operated by a particular finger (normally, it is the thumb) of the user.

In the keyboard, however, since this is basically designed so as to execute key operation using both hands of the user, an outward shape of the keyboard becomes large so that it is very inconvenient when using it with portable equipment. Further, there are many input keys on the keyboard and much time is required to learn and master the key input operation. Further, since both hands are necessary for executing a key operation it is difficult to write characters using any one hand, for example, while making a phone call or taking a memo.

Still further, in the key input device which can be gripped by one hand, plural input keys are very closely arranged in a narrow area on the key input device. This is because it is basically designed for one-finger use when inputting characters, numerals and the like.

In particular, when inputting Japanese hiragana, a user must push one button again and again in order to obtain a desired vowel and consonant. As a result, many operations of pushing a button is required for the user.

### SUMMARY OF THE INVENTION

The object of the present invention is to provide a key input device used for portable equipment in which a user can easily grip the key input device and easily execute an input operation for characters with few operations of pushing buttons using one hand of the user.

In accordance with a first aspect of the present invention, there is provided a key input device including: a key holding unit having an outward shape which can be gripped by one hand; and at least five input keys which are provided on the key holding unit so as to allow separate operation of each of at least five input keys using each finger of one hand; wherein input of characters is executed by operating at least five input keys.

In accordance with a second aspect of the present invention, there is provided a key input device including: a key holding unit having an outward shape which can be gripped by one hand and is structured as a separate part which is portable; at least five input keys which are provided on the key holding unit so as to allow separate operation of each of at least five input keys using each finger of one hand; and input units which are provided on the key holding unit in addition to at least five input keys, and which are operated in accordance with the movement of the key holding unit; wherein input of characters are executed by combining at least five input keys with the input units.

In accordance with a third aspect of the present invention, there is provided a key input device including; at least five input keys arranged so as to be operated separately by each finger of one hand; and wherein each at least five input keys corresponding to each finger of one hand inputs a different vowel in the Japanese.

In accordance with a fourth aspect of the present invention, there is provided a key input device including: a portable key holding unit having an approximately-rectangular parallelepiped shape and can be gripped by one hand; and a plurality of input keys provided on the key holding unit so as to be operated separately by one hand; wherein input of characters is executed by operating said plurality of input keys.

### BRIEF DESCRIPTION OF THE DRAWINGS

FIG. 1 is a schematically perspective view of a key input device according to a first embodiment of the present invention;

FIG. 2 is a schematically perspective view of the key input device in which a cover is removed in FIG. 1;

FIG. 3 is a schematic block diagram of a control circuit according to the first embodiment of the present invention;

FIGS. 4A to 4C show the contents of the table stored in the memory in FIG. 3;

FIG. 5 shows a timing chart of ON/OFF of the switches SW1 to SW7 and a resultant output after determination by the MPU 27;

FIG. 6A shows the case that the key input device is connected to the portable telephone terminal through the connector 29;

FIG. 6B shows the case that the key input device is connected to the portable information terminal through the connector 29;

FIG. 7 is a view for explaining the second embodiment;

FIG. 8 is a view for explaining the third embodiment;

FIG. 9 is a view for explaining the fourth embodiment;

FIG. 10 is a view for explaining the fifth embodiment;

FIG. 11 is a view for explaining the sixth embodiment; and

FIG. 12 is a view for explaining the seventh embodiment.

### DESCRIPTION OF PREFERRED EMBODIMENTS

The preferred embodiments will be explained in detail with reference to the attached drawings.

(FIRST EMBODIMENT)

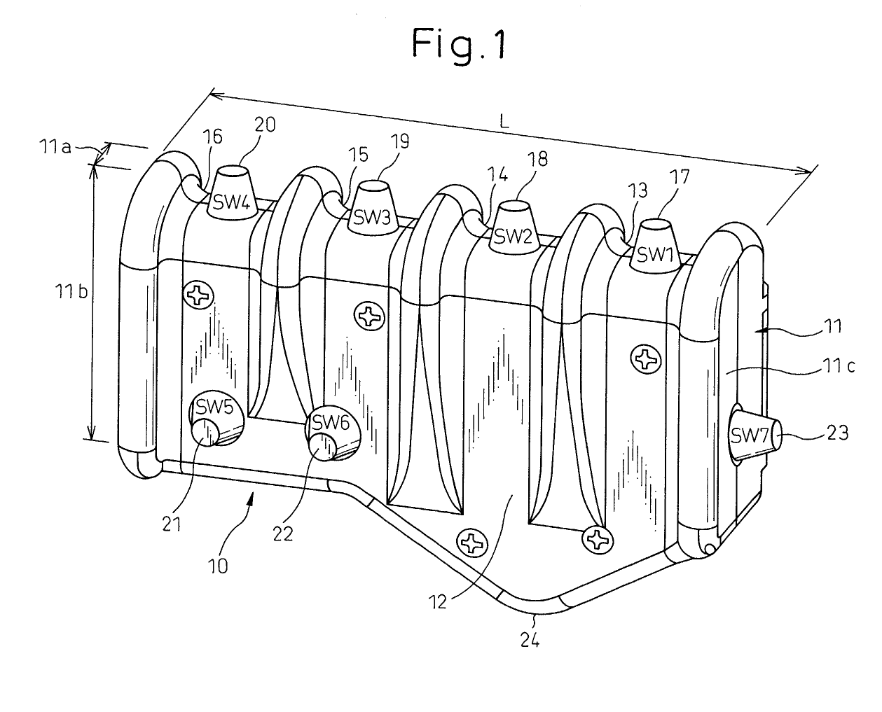

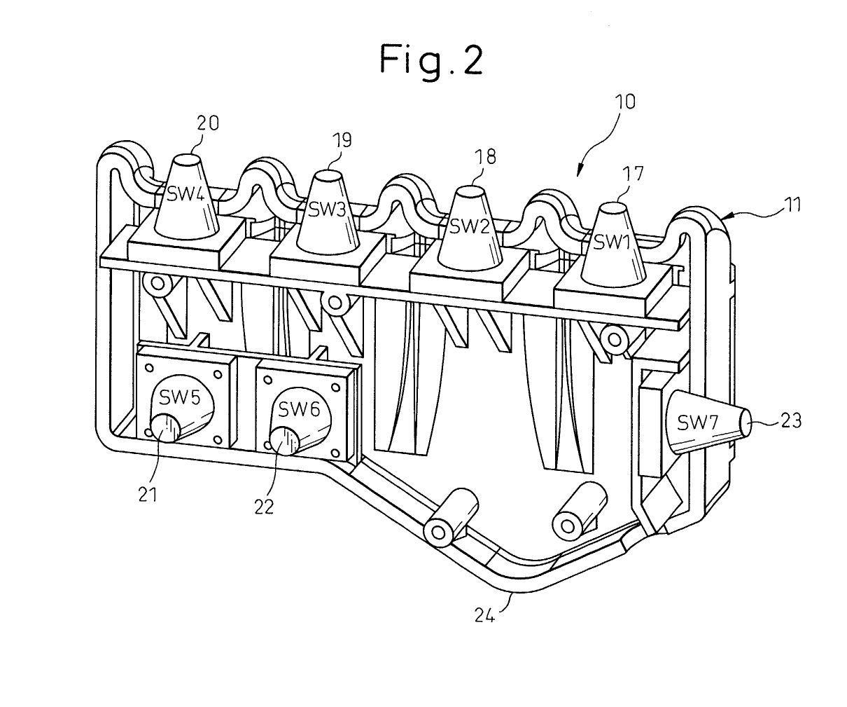

FIG. 1 is a schematically perspective view of a key input device according to a first embodiment of the present invention, and FIG. 2 is a schematically perspective view of the key input device in which a cover is removed in FIG. 1. A key input device 10 includes a housing member 11 which forms a key holding portion having a grip-shape which is formed so as to be held by one hand. A cover 12 is mounted to a part of the housing member 11. The housing member 11 and cover 12 can be formed of, for example, a resin. In this case, the cover 12 is detachable from the housing member 11 through hook-like member or screw-like member.

The entire structure of the housing member 11 including the cover 12 has an approximately rectangular parallelepiped shape which is elongated with rectangular-cross sectional shape having rounded corners. In this case, the total length L at the longitudinal direction is slightly larger than a height of the grip-shape of one hand of a user. Further, in a surface 11a (see upper portion of FIG. 1, i.e., a surface of a short-side of the cross section of the housing member 11), there are four concave portions 13 to 16, i.e., a concave portion 13 for the little finger, a concave portion 14 for the ring finger, a concave portion 15 for the middle finger and a concave portion 16 for the forefinger in accordance with one hand of the user. These concave portions 13 to 16 are sequentially provided at the longitudinal direction. Further, four push-button type input keys 17 to 20 are provided to corresponding concave portions 13 to 16.

As shown in FIG. 1, each concave portion 13 to 16 is formed so as to be elongated from the surface 11a to a surface 11b (see lower portion of FIG. 1, i.e., a surface of a long-side of the cross section of the housing member 11). In this case, each concave portion 13 to 16 is also formed in a rear surface (not shown) of the housing member 11.

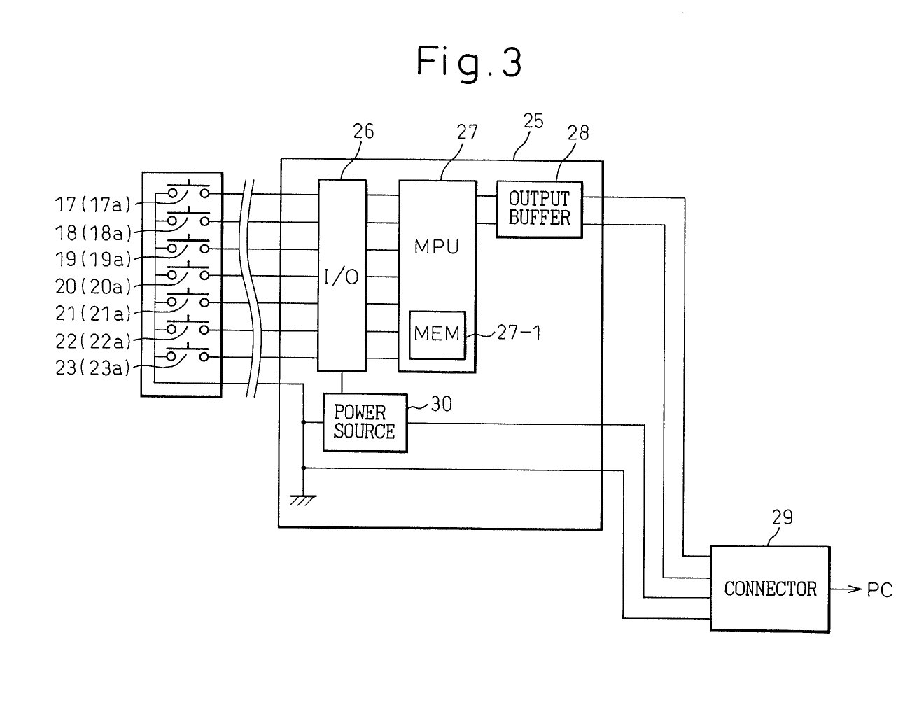

Accordingly, the user can easily and tightly grip the concave portions 13 to 16 of the housing member 11 using the four fingers by one hand so that the user can surely and separately operate the input keys 17 to 20 using the four fingers when the user grips the housing member 11 by one hand. The input keys 17 to 20 are used for opening and closing first to fourth switches 17a to 20a shown in FIG. 3.

Further, two push-button type input keys 21 and 22 for the thumb are provided to the surface 11b of the housing member 11. Since the thumb is close to the middle finger and the forefinger in the gripping state, the push-button type input keys 21 and 22 are arranged at the position each corresponding to the input key 19 for the middle finger and the input key 20 for the forefinger in the longitudinal direction of the housing member 11.

As explained above, two input keys 21 and 22 for the thumb are provided because the thumb can be used freely when the user grips the housing member 11. The input keys 21 and 22 are used for opening and closing a fifth and sixth switches 21a and 22a in FIG. 3.

Further, a seventh push-button type input key 23 is provided at the end surface 11c in the longitudinal direction of the housing member 11 (see right end surface of FIG. 1). The input key 23 is used for opening and closing a seventh switch 23a in FIG. 3. In this case, the housing member 11 is moved by utilizing motion of the wrist or arm of the user, and the seventh switch 23a can be turned on or turned off by touching the input key 23 to the back or leg of the user. Further, the seventh switch 23a can be turned on or turned off by touching the input key 23 to, for example, a desk, the inside of a car and the like.

Further, in the housing member 11, a projecting portion 24 is provided on another surface which is opposite to the concave portion 13 for the little finger and the concave portion 14 for the ring finger so that it is possible to easily set the grip position of the thumb.

The grip portions (i.e., concave portions) of the housing member 11 in FIG. 1 are structured for the left hand. Accordingly, the projecting portion 24 is put on the flat of the left hand, and each concave portion 13 to 16 is gripped by corresponding finger of the left hand so that it is possible to easily operate two input keys 21 and 22 using the thumb of the left hand.

FIG. 3 is a schematic block diagram of a control circuit according to the first embodiment of the present invention. The control circuit 25 is provided in the inside of the housing member 11. Basically, the control circuit 25 detects an open or close signal sent from each of the first to seventh switches 17a to 23a, each of which is opened or closed by the corresponding input key 17 to 23, and outputs a predetermined output signal.

Concretely, the first to seventh switches 17a to 23a are connected to a microcomputer unit (MPU) 27 through an input/output circuit (I/O) 26. The output signal processed by the MPU 27 is output to an external stage (for example, an external computer such as personal computer PC (not shown)) through an output buffer circuit 28. Accordingly, the output buffer circuit 28 is electrically connected to a connector 29 through lead wires, and the connector 29 is connected to the external computer PC. Further, the control circuit 25 includes a buttery 30 for supplying a power to all circuits in the control circuit 25.

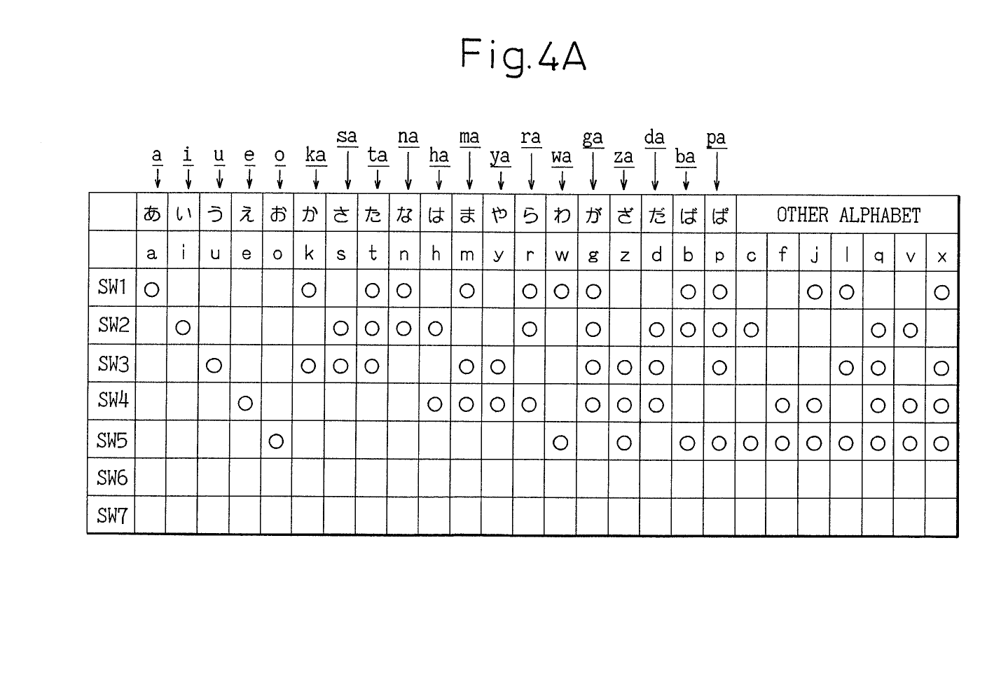

The MPU 27 includes a memory (MEM) 27-1 which stores a program for communication for the external computer, and a table for explaining key arrangement shown in FIG. 4 so that it is possible to easily change the key arrangement and a communication protocol for the external computer.

FIGS. 4A to 4C show the contents of the table stored in the memory 27-1 in FIG. 3. Each mark “∘” shows turning-on of the switches SW1 to SW7 (i.e. The switch is closed) each of which is opened or closed by the corresponding input key 17 to 23. FIG. 4A shows the table of Romaji-to-Japanese kana conversion, and explains the relationship between Romaji-kana-input (i.e., Japanese kana is input by using Romaji (Roman alphabet)) and turning-on of the switch. The Romaji-kana-input can be executed by the first to fifth switches 17a to 21a (i.e. SW1 to SW5) which can be operated using five fingers.

That is, each of the first to fifth switches 17a to 21a (SW1 to SW5) can separately input the Japanese vowels (i.e. “a” “i” “u” “e” “o”) in accordance with turning-on of the switch. Concretely, the vowel “a” is input by the first switch 17a (SW1) for the little finger, the vowel “i” is input by the second switch 18a (SW2) for the ring finger, the vowel “u” is input by the third switch 19a (SW3) for the middle finger, the vowel “e” is input by the fourth switch 19a (SW4) for the forefinger and the vowel “o” is input by the fifth switch 20a (SW5) for the thumb.

Further, by combining each consonant (k, s, t, etc.) with the vowel, the Japanese “hiragana”, for example, “ka” “sa” “ta” etc. is structured, and the hiragana can be input by simultaneously pushing any switches 17a to 21a (SW1 to SW5). For example, the hiragana “ka” is input by simultaneously pushing two switches SW1 and SW3 and pushing the switch SW1, “ta” is input by simultaneously pushing three switches SW1 to SW3 and pushing the switch SW1, and “pa” is input by simultaneously pushing four switches SW1 to SW3 and SW5 and pushing the switch SW1.

Concrete example of the Romaji-kana-input by using the first to fifth switches 17a to 21a (SW1 to SW5) will be explained in detail below. For example, the following operations are performed through these switches when inputting the Japanese name “ITOU DAISUKE”.

(1) The vowel “i” is input by turning on the second switch 18a (SW2) pushing the input key 18 for the ring finger.

(2) The hiragana “to” is input by turning on the first, the second and the third switches 17a to 19a (SW1 to SW3) simultaneously pushing three input keys 17 to 19 in order to select the consonant “t”, and input by turning on the fifth switch 21a (SW5) pushing the input key 21 for the thumb in order to select the vowel “o”. As a result, the hiragana “to” is input.

(3) The vowel “u” is input by turning on the third switch 19a (SW3) pushing the input key 19 for the middle finger.

(4) The hiragana “da” is input by turning on the second, the third and the fourth switches 18a to 20a (SW2 to SW4) simultaneously pushing three input keys 18 to 20 in order to select the consonant “d”, and input by turning on the first switch 17a (SW1) pushing the input key 17 for the little finger in order to select the vowel “a”. As a result, the hiragana “da” is input.

(5) The vowel “i” is input by turning on the second switch 18a (SW2) pushing the input key 18 for the ring finger.

(6) The hiragana “su” is input by turning on the second and the third switches 18a and 19a (SW2 and SW3) simultaneously pushing two input keys 18 and 19 in order to select the consonant “s”, and input by turning on the third switch 19a (SW3) pushing the input key 19 for the middle finger in order to select the vowel “u”. As a result, the hiragana “su” is input.

(7) The hiragana “ke” is input by turning on the first and the third switches 17a and 19a (SW1 and SW3) simultaneously pushing two input keys 17 and 19 in order to select the consonant “k”, and input by turning on the fourth switch 20a (SW4) pushing the input key 20 for the forefinger in order to select the vowel “e”. As a result the hiragana “ke” is input.

As explained above, it is possible to input the Japanese name “ITOU DAISUKE” in accordance with key operations from steps (1) to (7). That is, by separately operating the five input keys 17 to 21 (i.e. the first to fifth switches 17a to 21a) or by simultaneously operating at least two input keys, it is possible to input all Romaji and hiragana using five fingers of the left hand. Further, the conversion from the hiragana to the Chinese character can be executed using a space key (SP) explained below.

FIG. 4B shows the table for explaining key operations when inputting numerals. The sixth switch 22a (SW6) is always turned on using the input key 22 for the thumb. Further, the first to fourth switches 17a to 20a (SW1 to SW4) are simultaneously turned on using the input keys 17 to 20. For example, the numeral “3” is input by simultaneously turning on the first, the second and the sixth switches SW1, SW2 and SW6, and the numeral “9” input by simultaneously turning on the first, the fourth and the sixth switches SW1, SW4 and SW6. The numeral “0” is input by simply turning on the sixth switch SW6.

FIG. 4C shows the table for explaining key operations when inputting other symbols necessary for, for example, drafting sentences. SP is used for converting the hiragana to the Chinese character. Two patterns are provided for the SP. One is turned on the seventh switch 23a (SW7) using the input key 23 provide at the end of the housing member 11, and the other is simultaneously turned on the first and fourth switches 17a and 20a (SW1 and SW4) using the input keys 17 and 20.

In FIG. 4C, CR denotes “determination” or “beginning of a new line”; ESC denotes “escape”; BS denotes “the back space”; F6 denotes “hiragana conversion”; F7 denotes “katakana conversion”; F8 denotes “half space of character”; F9 denotes “conversion to Romaji”; SHIFT denotes “switching between large and small characters”; and KAN (Chinese character) denotes “switching of input mode conversion”. Further, four arrows denotes “moving direction of cursor”. For example, when the user moves the cursor to the right direction (→), the first and seventh switches SW1 and SW7 are simultaneously turned on using the input keys 17 and 23.

When the user operates input keys (SW1, SW3, SW5 and SW6) which correspond to “KAN” indicating the switching of input mode conversion, it is possible to select the Romaji-kana-conversion mode. Further, it is possible to select an alphabet-input mode by operating these input keys which correspond to “KAN”. When the user selects the alphabet-input mode, it is possible to input each alphabet shown in FIG. 4A so that it is possible to edit the English sentence.

In the first embodiment, by operating seven switches 17a to 23a (i.e. seven bits), it is possible to determine 128 kinds of input patterns because of a binary number of on/off (1, 0), 7 (bits)=2⁷=128.

Accordingly, in the key arrangement shown in FIGS. 4A, 4B and 4C, it is possible to input total one hundred and twelve characters, i.e., twenty-six characters (for the alphabet), ten characters (for the numeral), forty-six characters (for the kana-character), and about thirty (for the special symbols).

In actual key operation by the user, it is impossible to simultaneously push plural input keys at the same timing. Accordingly, the microcomputer (MPU) 27 in FIG. 3 executes the following processes in order to determine simultaneous operation of the input keys as explained below.

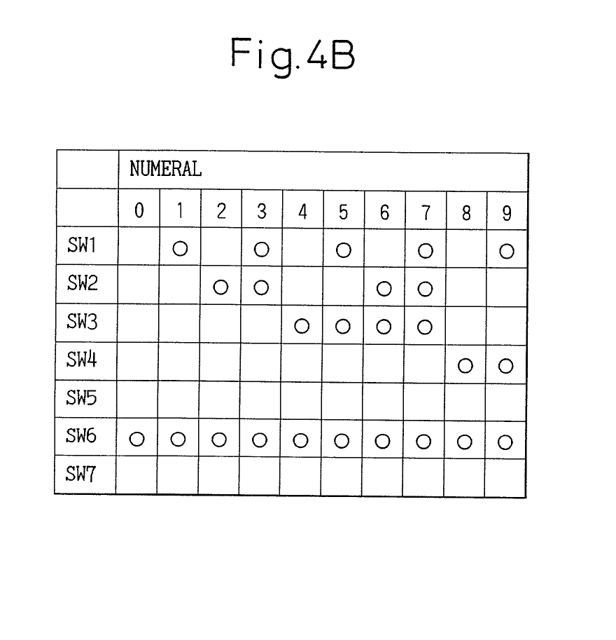

FIG. 5 shows a timing chart of ON/OFF of the switches SW1 to SW7 and a resultant output after determination by the MPU 27. As is obvious from the timing chart, each turning-on timing of the switch SW1, SW2 and SW5 is slightly different one another because it is very difficult for the user to simultaneously push these switches SW1, SW2 and SW5 in the actual key operation.

In this case, the MPU 27 sequentially stores each turning-on timing of the switch SW1, SW2 and SW5. Next, the MPU 27 generates a determination output by detecting the timing when any one of switches is first turned off (i.e. the switch SW5 is first turned off in this example) and by detecting turning-on of all switches SW1, SW2 and SW5 which are turned on just before the switch SW5 is turned off. Based on the determination output, the MPU 27 transmits predetermined protocols corresponding to turning-on of these switches SW1, SW2 and SW5 to the external computer. Accordingly, it is possible to detect turning-on of plural switches as simultaneous timing, even if turning-on timing of these switches is slightly shifted in actual key operation by the user.

The merits, in actual use, of the first embodiment of the present invention will be explained in detail below.

(1) The housing member 11 of the key input device 10 is compact and can be gripped by one hand. Accordingly, the user can easily carry the device 10 by one hand so that the device 10 has a superior portable performance. Therefore, the user can handle the device 10 in various environments, for example, in a commuter train, in a car, in a home, and the like.

(2) The concave portions 13 to 16 corresponding to the little finger, the ring finger, the middle finger and the forefinger are formed on the housing member 11, and the push-button type input keys 17 to 19 are provided in the concave portions 13 to 16. Accordingly, the user can easily grip the device 10 and can surely operate these input keys so that it is possible to prevent a mistake in the key operation by the user. As a result, in actual use of the device 10, for example, in use of a portable telephone with the device 10, it is possible to prevent the mistake in the key operation when the user inputs telephone numbers.

(3) The push-button type input keys 17 to 21 corresponding to five fingers are set as particular keys for inputting the vowels “a”, “i”, “u”, “e” and “o”. Further, the Japanese hiragana is input, first by selecting the consonant, and next by selecting the vowel. For example, the hiragana “ta” is input by selecting the consonant “t” and by selecting the vowel “a” using the switches SW1 to SW3 and SW1. According to the above key operation, it is possible to easily input the vowel with one action of the switch, and to easily input the hiragana based on combination of plural switches. As a result, it is possible to reduce the key operation when inputting a message in comparison with the key operation at a conventional portable telephone.

(4) Further, in addition to five input keys 17 to 21 used as the particular keys for inputting the vowels, the input key 22 for the thumb which can freely move is provided to the surface 11b of the housing 11, and the input key 23 is provided to one end surface 11c of the housing member 11. Accordingly, by providing the seven input keys 17 to 23 in total, it is possible to input one hundred and twenty-eight patterns (characters, symbols, numerals and the like) in the case of the binary number, as mentioned above. As a result, it is possible to sufficiently handle almost all characters and symbols generally used.

(5) According to the experience of the inventor of the present invention, in the case of the alphabet and numerals, it is possible to learn key arrangement and operations thereof in an hour. Accordingly, the user can easily input characters and numerals by watching a display of the portable telephone without watching the key arrangement so that it is possible to provide very high operability.

(6) In particular, the input key 23 provided at the end surface 11c in the longitudinal direction of the housing member 11 can be operated by utilizing motion of the wrist and by contacting it to a part of the user's body, for example, the back or leg of the user, or the surrounding equipments, for example, a desk or the inside of the car. As a result, the user can rhythmically execute key input operations.

In the Romaji-kana-conversion mode, since the role of the space key for executing conversion of the Chinese character is applied to the input key 23, it is possible to execute efficiently and rhythmically the conversion of the Chinese character, which is frequently executed by the user.

Since the input key 23 has the role of the space key, when the alphabet input mode is selected in the input mode conversion, it is possible to input the “space” between words in the English sentence by operating the input key 23. Accordingly, it is possible to execute efficiently and rhythmically input operation of the “space” having high frequency.

(7) Further, as explained by “SP” in FIG. 4C, two input operations, i.e. one operation using only the input key 23 (see switch SW7 in FIG. 4C), and the other operation using two input keys 17 and 20 (see switches SW1 and SW4 in FIG. 4C), are provided as the key operation in the present invention. Accordingly, the user can input the space in accordance with the working environment. For example, the user can input the space by simultaneously pushing two input keys 17 and 20 in a working environment which does not allow swinging of the wrist or arm.

(Modified examples of the first embodiment)

The above first embodiment is provided to mainly explain the case that the output of the key input device 10 is connected to the external computer. The following explanation is given to a modified example.

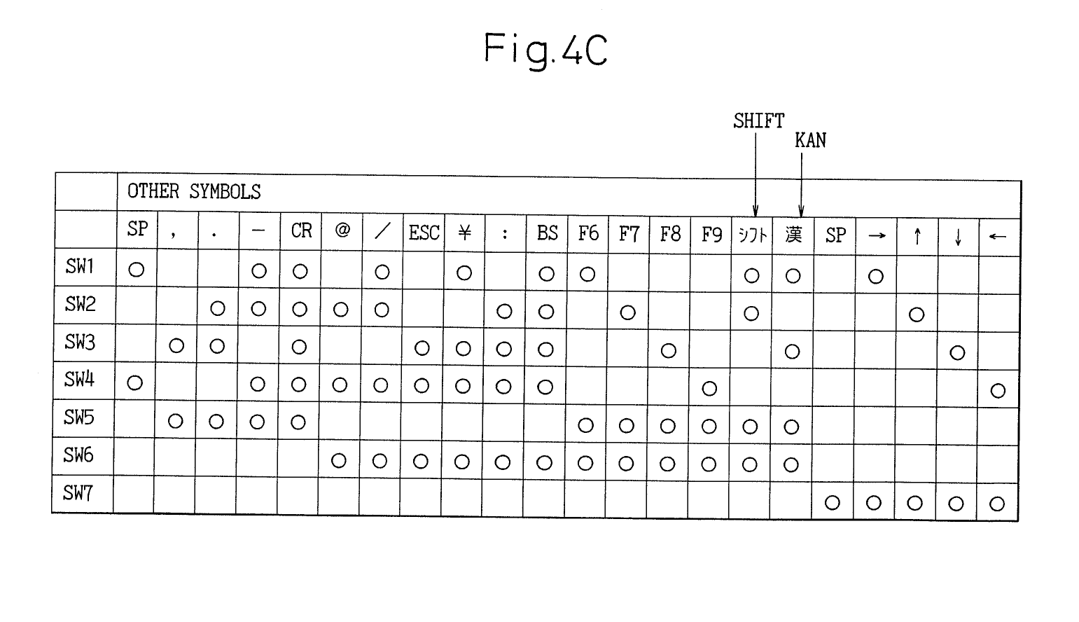

FIG. 6A shows the case that the key input device 10 is connected to the portable telephone terminal 40 through the connector 29, and FIG. 6B shows the case that the key input device 10 is connected to the portable information terminal 41 through the connector 29.

Further, in the first embodiment, although the output of the key input device 10 is connected to the external computer through the lead wire and connector 29, it is possible to connect the output of the key input device 10 to the external computer by wireless.

Further, in the first embodiment, although a total of seven input keys, i.e. the input keys 17 to 22 operated by the five fingers and the input key 23 operated by utilizing motion of the wrist, are provided as the input keys, it is possible to increase or decrease the number of the input keys, for example, five, six or eight input keys, if there is an increase or decrease of input items in accordance with use.

Still further, if the number of the input keys is increased to eight input keys, the seventh input key 23 is arranged at the end surface 11c in the longitudinal direction of the housing member 11 as mentioned above, and an eighth input key is newly arranged at another end surface (i.e. a left end surface in FIGS. 1 and 2) in the longitudinal direction of the housing member 11. Accordingly, the user can operate the seventh and eighth input keys when the device 10 is moved in both directions in the longitudinal direction.

(SECOND EMBODIMENT)

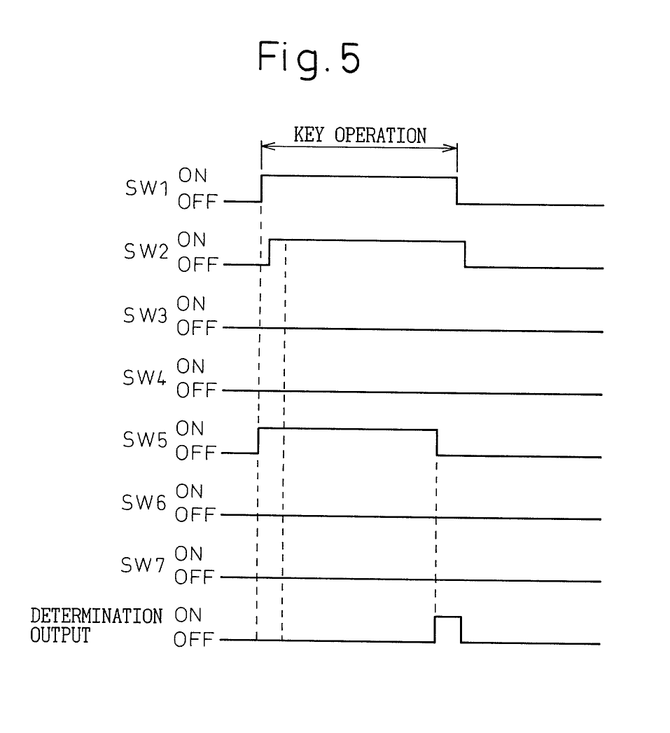

FIG. 7 is a view for explaining the second embodiment. As explained above, in the first embodiment, the user executes the key input operation using the seventh input key 23 by utilizing motion of the wrist and by contacting this key with a part of the body, for example, the back or a leg, or the surrounding equipment.

On the other hand, in the second embodiment, as shown in FIG. 7, a vibration-detecting sensor 42 (see dotted circle) is provided on the housing member 11. The housing member 11 is moved in the direction shown by the arrow A (i.e. the direction orthogonal to the longitudinal direction of the housing member 11) and the vibration-detecting sensor 42 detects the movement of the housing member 11.

Accordingly, it is possible to replace the seventh input key 23 with the vibration-detecting sensor 42. In this case, since the user can execute key input operation by activating the vibration-detecting sensor 42 in accordance with movement of the housing member 11 in the direction orthogonal to the longitudinal direction, it is possible to reduce motion of the one hand compared to the first embodiment.

(THIRD EMBODIMENT)

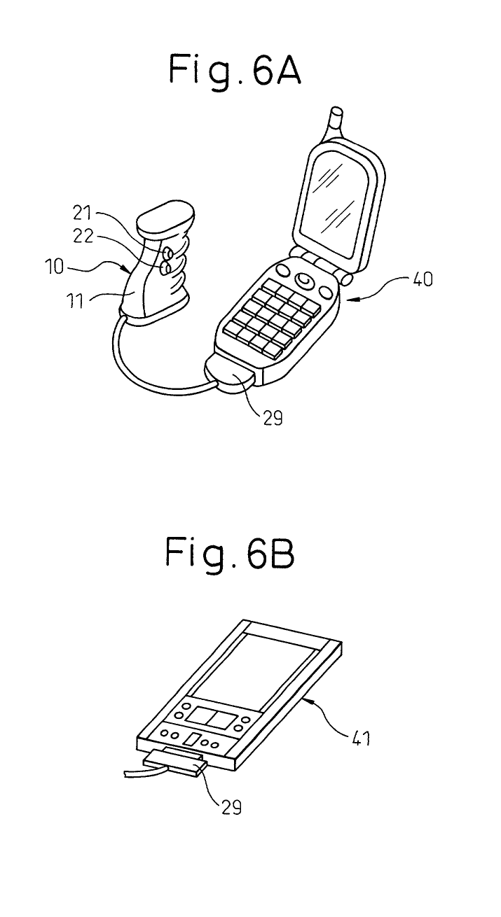

FIG. 8 is a view for explaining the third embodiment. In this embodiment, the key input device is mounted to a handle portion 43 of a steering wheel apparatus. That is, grip portions 44 and 45 for both hands of a driver are provided on the handle portion 43. Further, five concave portions corresponding to five fingers are provided on each of grip portions 44 and 45, and five input keys 17 to 21 which are pushed by the driver are provided on each concave portions.

In this case, the relationship between the input keys 17 to 21 and five fingers corresponds to that of the first embodiment. As shown in the drawing, the turning-on/off signals generated by these input keys 17 to 21 are input to a computer system 46 such as a car navigation system.

Further, the driver can input characters, numerals, and the like by pushing the input keys 17 to 21 using the left hand or the right hand so that it is possible to realize the function of the car navigation system by transmitting operation signals through the input keys 17 to 21.

Still further, as another modified example of the third embodiment, it is possible to mount the key input device according to the present invention on an operation knob of a transmission lever (i.e. shift lever) of the car.

(FOURTH EMBODIMENT)

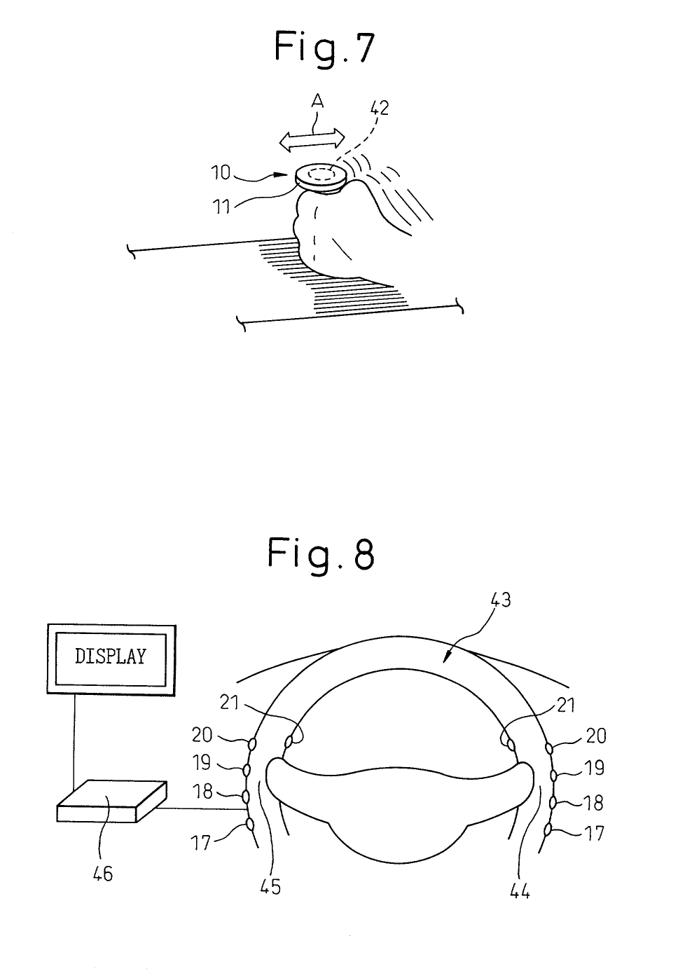

FIG. 9 is a view for explaining the fourth embodiment. Number 47 is a remote controller used for a car navigation system, an audio system, a TV receiver system and the like. The key input device according to the present invention can be easily applied to the above known systems. As shown in the drawing, the remote controller 47 includes the input keys 17 to 22 (SW1 to SW6) operated by the five fingers gripping the remote controller 47, and the input key 23 (SW7) operated by utilizing motion of the wrist, in addition to operational switches 48 used for operating the system. According to this structure, it is possible to output the operation signal for the system from the operational switches 48, and to output characters, numerals and the like to the display from the input keys 17 to 22 and 23.

(FIFTH EMBODIMENT)

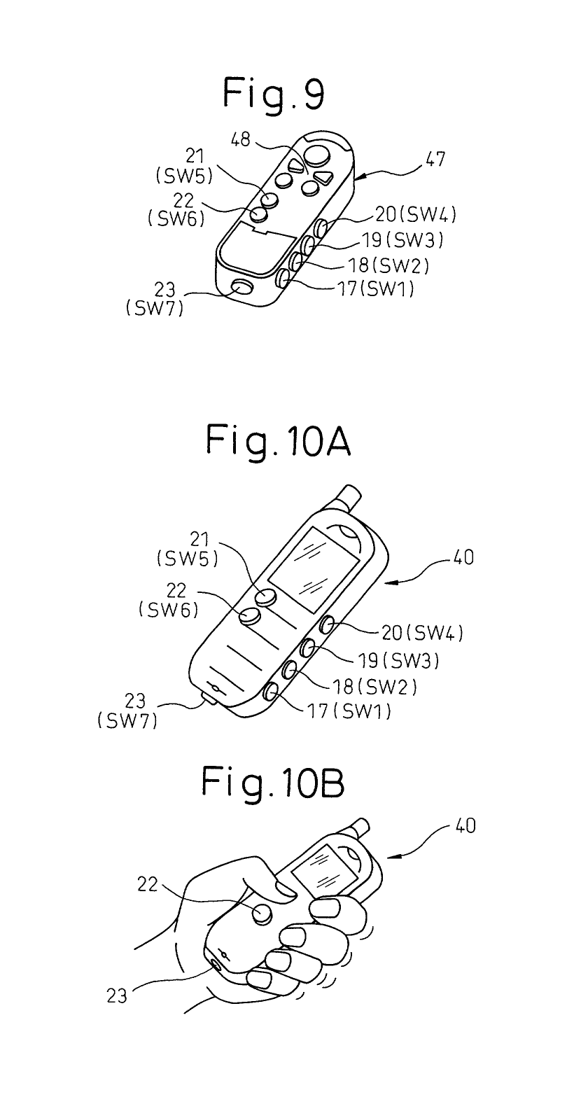

FIGS. 10A and 10B are views for the fifth embodiment. Number 40 is a portable telephone. The key input device according to the present invention can be easily applied to the portable telephone. That is, as shown in FIG. 10A, the portable telephone 40 includes the input keys 17 to 22 (SW1 to SW6) operated by the five fingers gripping the portable telephone 40, and the input key 23 (SW7) operated by utilizing motion of the wrist. According to this structure, the user can easily input characters, numerals and the like by operating these input keys. As shown in FIG. 10B, the user can easily grip the portable telephone 40, easily operate the input keys 17 to 20 (SW1 to SW4) using four fingers, easily operate the input key 21 or 22 (SW5 or SW6) using the thumb, and easily operate the input key 23 by utilizing motion of the wrist.

According to key arrangement of the fifth embodiment, it is possible to considerably improve operability of the input keys compared to the key arrangement of a conventional portable telephone. This is because, although the input keys are very small and arranged on the very narrow space in the conventional portable telephone, and operated by only using the thumb, in the present invention, the user can easily operate the input keys 17 to 20 (SW1 to SW4) using four fingers, easily operate the input key 21 or 22 (SW5 or SW6) using the thumb, and easily operate the input key 23 by utilizing motion of the wrist.

In this case, an outward shape of the grip of the remote controller 47 in FIG. 9 and the portable telephone 40 is linearly formed. However, it is possible to form the outward shape of the grip so as to have concave portions adapting to the five fingers as shown in FIGS. 1 and 2.

Further, as well as the portable telephone 40, it is possible to directly mount the input keys 17 to 22 and the input key 23 on the portable information terminal 41 shown in FIG. 6B. According to this structure, it is possible to considerably improve the operability of the key input on the portable information terminal 41.

(SIXTH EMBODIMENT)

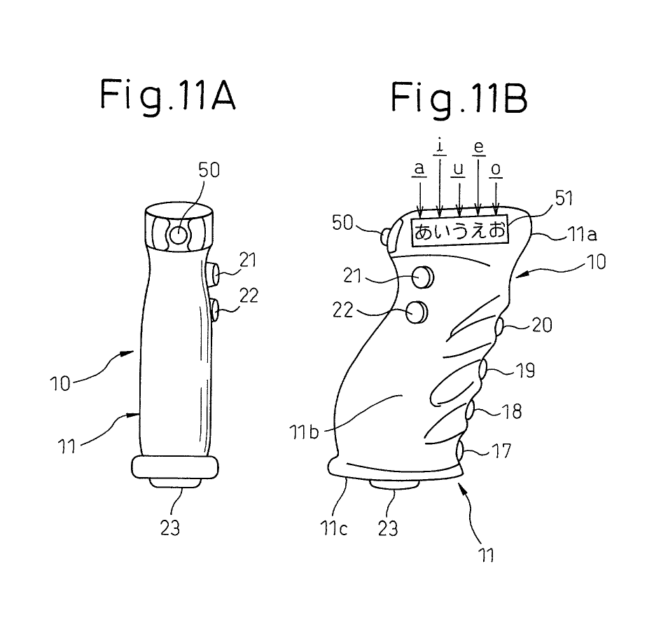

FIG. 11 is a view for explaining the sixth embodiment. The key input device 10 further includes an input key 50 having the function of a mouse of the computer and a display area 51 on the housing member 11. According to this key input device, it is possible to realize all input operations for the computer by using one hand, instead of a mouse and a keyboard.

(SEVENTH EMBODIMENT)

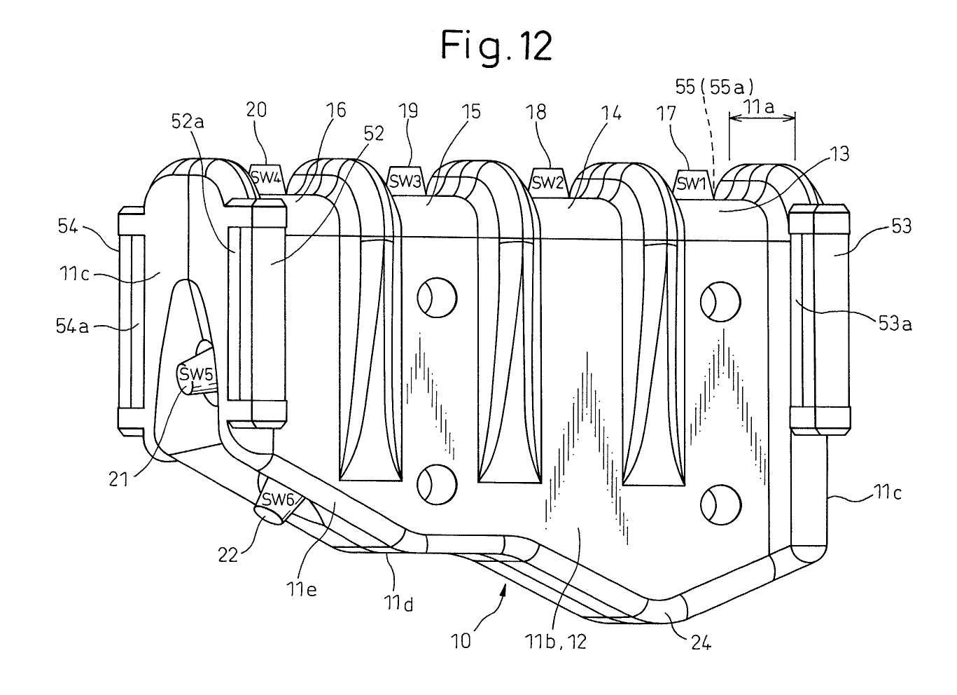

FIG. 12 is a view for explaining the seventh embodiment. In the above explanations, the key arrangement of the key input device 10 is designed as use of the left hand of the user. That is, in the above embodiments, two push-button type input keys 21 and 22 for the thumb is arranged at the end surface 11b in the longitudinal direction of the housing member 11 so that the user can easily operate the input keys 21 and 22 using the left hand. In the seventh embodiment, the key arrangement of the input keys 21 and 22 for the thumb is designed so as to be operable by the left hand or the right hand. That is, the key input device 10 according to the seventh embodiment can be used by not only the left hand, but also the right hand.

As shown in FIG. 12, as well as the first to sixth embodiments, the concave portions 13 to 16 and the input keys 17 to 20 (SW1 to SW4) are provided on the surface of the housing member 11, corresponding the four fingers, i.e. the little finger, the ring finger, the middle finger and forefinger. Further, in the seventh embodiment, a shoulder portion 11e is provided adjacent to the surface 11c on a surface 11d opposite to the surface 11a.

The slanted portion of the shoulder portion 11e is close to the end surface 11a of the input key 20 in near of the end surface 11c.

Further, the push-button type input keys 21 and 22, both of which are operated by the thumb, are on the slanted shoulder portion 11e. Although it is not shown in this drawing, the push-button input key 23 is arranged on the end surface of the 11c (the side of the input key 17), as well as the first embodiment.

According to this key arrangement, the input keys 21 and 22 for the thumb are arranged to the side opposite to the input key 20 for the forefinger, on the surface 11d. Accordingly, even if the user grips the housing member 11 using the left hand or the right hand, the input keys 21 and 22 for the thumb can be positioned close to the thumb of the left hand and the thumb of the right hand. As a result, it is possible to operate the input keys 17 to 20 and the input keys 21 and 22 using the left and right hands.

That is, in the case of the left hand, the flat portion of the left hand is contacted to the back surface of the housing member 11 (i.e. the back of the drawing (not shown)) so as to grip the housing member 11 using the little, the ring and the middle fingers and the forefinger. According to this grip, it is possible to push the input keys 17 to 20 using the little, the ring and the middle fingers and the forefinger of the left hand, and to push the input keys 21 and 22 using the thumb of the left hand.

Further, in the case of the right hand, the flat portion of the right hand is contacted to the front surface of the housing member 11 (i.e. the front of the drawing) so as to grip the housing member 11 using the little, the ring and the middle fingers and the forefinger. According to this grip, it is possible to push the input keys 17 to 20 using the little, the ring and the middle fingers and the forefinger of the right hand, and to push the input keys 21 and 22 using the thumb of the right hand.

As explained above, according to the seventh embodiment, it is possible to easily operate the key input device 10 using the left hand or the right hand.

Further, in the seventh embodiment, four belt holders 52 to 55 are provided on the surface 11b at both ends of the housing member 11 in the longitudinal direction thereof. In this case, the belt holder 55 is hidden because it is located at the back in the drawing.

Each of the belt holders 52 to 55 has a corresponding hole portion 52a to 55a. Accordingly, when the user grips the housing member 11 using the right hand, a belt of the user is passed through the hole portions 52a and 53a of the belt holders 52 and 53 so that the user can easily and surely hold the housing member 11 using the right hand.

Similarly, when the user grips the housing member 11 using the left hand, the belt of the user is passed through the hole portions 54a and 55a of the belt holders 54 and 55 so that the user can easily and surely hold the housing member 11 using the left hand.

(ADDITIONAL EMBODIMENT)

(1) Although the display 51 is provided on the key input device 10 as shown in FIG. 11, and the memory (MEM) 27-1 is provided in the microcomputer (MPU) 27 as shown in FIG. 3, the MPU 27 can further include another memory for storing input characters and a character conversion unit for inputting the Japanese. As a result, it is possible to confirm the input characters on the display and to store them by the key input device itself, even if there are no computers such as a personal computer and portable information terminal 41. Further, after display and storage, it is possible to transmit the input information, which are stored in the personal computer and the portable information terminal 41, to the external computer.

(2) Further, by providing a slot portion for inserting a memory device such as a compact flash memory, on the key input device 10, the input information can be temporarily stored in the memory device so that it is possible to transmit the input information to the personal computer through the memory device, without direct transmission of the input information to the personal computer.

(3) By mounting a thin and compact display in the inside of an umbrella, and by mounting the key input device 10 according to the present invention on the grip of the umbrella, it is possible to input the characters and the like when the user puts up the umbrella and walks in the rain. Further, it is possible to mount the key input device 10 on a grip of a bag or suitcase.

(4) By mounting the key input device 10 according to the present invention onto a joystick for a game machine, it is possible to easily input various instructions used for additional functions to increase the contents of the game from the key input device 10.

(5) By applying the key input device according to the present invention to a wearable computer (i.e. a computer wearing on a user's body), it is possible to easily operate the wearable computer in a jacket pocket of the user using input keys of the key input device 10. Accordingly, the key input device 10 is very effective as an input means of the wearable computer.

As a result, the key input device according to the present invention can be applied to all equipments which must be operated by one hand and require input characters and the like.

1. A key input device comprising:
a key holding unit having an outward shape which can be gripped by one hand; and
at least five input keys which are provided on said key holding unit so as to allow separate operation of each of said at least five input keys using each finger of one hand;
wherein input of characters is executed by operating said at least five input keys.

2. A key input device as claimed in claim 1, wherein said key holding unit is integrated with an equipment having other use.

3. A key input device as claimed in claim 1, wherein said key holding unit is structured as a separate part which is portable.

4. A key input device comprising:
a key holding unit having an outward shape which can be gripped by one hand and is structured as a separate part which is portable;
at least five input keys which are provided on said key holding unit so as to allow separate operation of each of said at least five input keys using each finger of one hand; and
input means which are provided on said key holding unit in addition to said at least five input keys, and which are operated in accordance with the movement of said key holding unit;
wherein input of characters are executed by combining said at least five input keys with said input means.

5. A key input device as claimed in claim 4, wherein one of said input means is operated by contacting it to another portion except for said key holding unit.

6. A key input device as claimed in claim 4, wherein each of said input means comprises a vibration detecting means for detecting the vibration of said key holding unit.

7. A key input device as claimed in claim 4, wherein each of said input means has a function of character conversion.

8. A key input device as claimed in claim 4, wherein said key holding unit has an approximately rectangular parallelepiped shape;
in said at least five input keys, four input keys operated by the little finger, the ring finger, the middle finger and the forefinger are provided on a first surface of a short-side of cross-section of said rectangular parallelepiped shape; and
in said at least five input keys, input keys operated by the thumb are provided on a second surface of a long-side of cross-section of said rectangular parallelepiped shape.

9. A key input device as claimed in claim 4, wherein said key holding unit has an approximately rectangular parallelepiped shape;
in said at least five input keys, four input keys operated by the little finger, the ring finger, the middle finger and the forefinger are provided on a first surface of a short-side of cross-section of said rectangular parallelepiped shape; and
in said at least five input keys, input keys operated by the thumb are provided on a position opposite to an input key operated by the forefinger, in a fourth surface opposite to said first surface.

10. A key input device as claimed in claim 9, wherein a shoulder portion is provided on a position opposite to said input key operated by the forefinger in said fourth surface; and
said input keys operated by the thumb are provided on said shoulder portion.

11. A key input device as claimed in claim 8, wherein plural said input keys operated by the thumb are provided.

12. A key input device as claimed in claim 8, wherein said input means are provided on at least one end surface of both end surfaces in a longitudinal direction of said rectangular parallelepiped shape.

13. A key input device as claimed in claim 1, wherein said key holding unit has four concave portions each corresponding to the little finger, the ring finger, the middle finger and the forefinger, when gripping said key holding unit by one hand; and
in said at least five input keys, four input keys operated by the little finger, the ring finger, the middle finger and the forefinger are provided on said concave portions.

14. A key input device comprising;
at least five input keys arranged so as to be operated separately by each finger of one hand; and
wherein each said at least five input keys corresponding to each finger of one hand inputs a different vowel in the Japanese.

15. A key input device as claimed in claim 14, wherein, in determination of Japanese hiragana including consonants, first, any one of consonants is selected simultaneously pushing at least two input keys in said five input keys, and second, any one of vowels “a”, “i”, “u”, “e”, “o” is selected pushing any one of said five input keys, so that the hiragana is structured by combining selected consonant with a selected vowel.

16. A key input device as claimed in claim 14 or 15, wherein a key holding unit has an outward shape which can be gripped by one hand, and is structured as a separate part which is portable;
input means are provided on said key holding unit, and operated by said at least five input keys, and operated in accordance with movement of said key holding unit;
wherein a function of character conversion is executed by said input means.

17. A key input device as claimed in claim 14, wherein plural said input keys operated by the thumb are provided;
one of said input keys operated by the thumb is used for inputting said vowels, and the other input keys is used for executing additional functions for preparation and edition of sentences.

18. A key input device comprising:
a portable key holding unit having an approximately-rectangular parallelepiped shape and can be gripped by one hand; and
a plurality of input keys provided on said key holding unit so as to be operated separately by one hand;
wherein input of characters is executed by operating said plurality of input keys.

19. A key input device as claimed in claim 1, wherein said key holding unit comprises a housing member which includes a control circuit for determining an operation signal generated by said input keys.
